(19) United States
(12) Patent Application Publication
(10) Pub. No.: US 2009/0103354 A1
(43) Pub. Date: Apr. 23, 2009

(54) Ground Level Precharge Bit Line Scheme for Read Operation in Spin Transfer Torque Magnetoresistive Random Access Memory

(75) Inventors: Sei Seung Yoon, San Diego, CA (US); Seung H. Kang, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 11/873,684

(22) Filed: Oct. 17, 2007

(51) Int. Cl. G11C 11/00; G11C 7/00

(52) U.S. Cl. 365/158; 365/203

(57) ABSTRACT

Systems, circuits and methods for read operations in Spin Transfer Torque Magnetoresistive Random Access Memory (STT-MRAM) are disclosed. A plurality of bit cells, each coupled to one of a plurality of bit lines, word lines and source lines are provided. A plurality of precharge transistors corresponding to one of the plurality of bit lines are configured to discharge the bit lines to ground prior to a read operation.

### FIELD OF DISCLOSURE

Embodiments of the invention are related to random access memory (RAM). More particularly, embodiments of the invention are related to read operations in Spin Transfer Torque Magnetoresistive Random Access Memory (STT-MRAM).

### BACKGROUND

Random access memory (RAM) is a ubiquitous component of modern digital architectures. RAM can be stand alone devices or can be integrated or embedded within devices that use the RAM, such as microprocessors, microcontrollers, application specific integrated circuits (ASICs), system-on-chip (SoC), and other like devices as will be appreciated by those skilled in the art. RAM can be volatile or non-volatile. Volatile RAM loses its stored information whenever power is removed. Non-volatile RAM can maintain its memory contents even when power is removed from the memory. Although non-volatile RAM has advantages in the ability to maintain its contents without having power applied, conventional non-volatile RAM has slower read/write times than volatile RAM.

Magnetoresistive Random Access Memory (MRAM) is a non-volatile memory technology that has response (read/write) times comparable to volatile memory. In contrast to conventional RAM technologies which store data as electric charges or current flows, MRAM uses magnetic elements. As illustrated in FIGS. 1A and 1B, a magnetic tunnel junction (MTJ) storage element 100 can be formed from two magnetic layers 110 and 130, each of which can hold a magnetic field, separated by an insulating (tunnel barrier) layer 120. One of the two layers (e.g., fixed layer 110), is set to a particular polarity. The other layer's (e.g., free layer 130) polarity 132 is free to change to match that of an external field that can be applied. A change in the polarity 132 of the free layer 130 will change the resistance of the MTJ storage element 100. For example, when the polarities are aligned, FIG. 1A, a low resistance state exists. When the polarities are not aligned, FIG. 1B, then a high resistance state exists. The illustration of MTJ 100 has been simplified and those skilled in the art will appreciate that each layer illustrated may comprise one or more layers of materials, as is known in the art.

Referring to FIG. 2A, a memory cell 200 of a conventional MRAM is illustrated for a read operation. The cell 200 includes a transistor 210, bit line 220, digit line 230 and word line 240. The cell 200 can be read by measuring the electrical resistance of the MTJ 100. For example, a particular MTJ 100 can be selected by activating an associated transistor 210, which can switch current from a bit line 220 through the MTJ 100. Due to the tunnel magnetoresistive effect, the electrical resistance of the MTJ 100 changes based on the orientation of the polarities in the two magnetic layers (e.g., 110, 130), as discussed above. The resistance inside any particular MTJ 100 can be determined from the current, resulting from the polarity of the free layer. Conventionally, if the fixed layer 110 and free layer 130 have the same polarity, the resistance is low and a “0” is read. If the fixed layer 110 and free layer 130 have opposite polarity, the resistance is higher and a “1” is read.

Referring to FIG. 2B, the memory cell 200 of a conventional MRAM is illustrated for a write operation. The write operation of the MRAM is a magnetic operation. Accordingly, transistor 210 is off during the write operation. Current is propagated through the bit line 220 and digit line 230 to establish magnetic fields 250 and 260 that can affect the polarity of the free layer of the MTJ 100 and consequently the logic state of the cell 200. Accordingly, data can be written to and stored in the MTJ 100.

MRAM has several desirable characteristics that make it a candidate for a universal memory, such as high speed, high density (i.e., small bitcell size), low power consumption, and no degradation over time. However, MRAM has scalability issues. Specifically, as the bit cells become smaller, the magnetic fields used for switching the memory state increase. Accordingly, current density and power consumption increase to provide the higher magnetic fields, thus limiting the scalability of the MRAM.

Unlike conventional MRAM, Spin Transfer Torque Magnetoresistive Random Access Memory (STT-MRAM) uses electrons that become spin-polarized as the electrons pass through a thin film (spin filter). STT-MRAM is also known as Spin Transfer Torque RAM (STT-RAM), Spin Torque Transfer Magnetization Switching RAM (Spin-RAM), and Spin Momentum Transfer (SMT-RAM). During the write operation, the spin-polarized electrons exert a torque on the free layer, which can switch the polarity of the free layer. The read operation is similar to conventional MRAM in that a current is used to detect the resistance/logic state of the MTJ storage element, as discussed in the foregoing. As illustrated in FIG. 3A, a STT-MRAM bit cell 300 includes MTJ 305, transistor 310, bit line 320 and word line 330. The transistor 310 is switched on for both read and write operations to allow current to flow through the MTJ 305, so that the logic state can be read or written.

Referring to FIG. 3B, a more detailed diagram of a STT-MRAM cell 301 is illustrated, for further discussion of the read/write operations. In addition to the previously discussed elements such as MTJ 305, transistor 310, bit line 320 and word line 330, a source line 340, sense amplifier 350, read/write circuitry 360 and bit line reference 370 are illustrated. As discussed above, the write operation in an STT-MRAM is electrical. Read/write circuitry 360 generates a write voltage between the bit line 320 and the source line 340. Depending on the polarity of the voltage between bit line 320 and source line 340, the polarity of the free layer of the MTJ 305 can be changed and correspondingly the logic state can be written to the cell 301. Likewise, during a read operation, a read current is generated, which flows between the bit line 320 and source line 340 through MTJ 305. When the current is permitted to flow via transistor 310, the resistance (logic state) of the MTJ 305 can be determined based on the voltage differential between the bit line 320 and source line 340, which is compared to a reference 370 and then amplified by sense amplifier 350. Those skilled in the art will appreciate the operation and construction of the memory cell 301 is known in the art. Additional details are provided, for example, in M. Hosomi, et al., A Novel Nonvolatile Memory with Spin Transfer Torque Magnetoresistive Magnetization Switching: Spin-RAM, proceedings of IEDM conference (2005), which is incorporated herein by reference in its entirety.

The electrical write operation of STT-MRAM eliminates the scaling problem due to the magnetic write operation in MRAM. Further, the circuit design is less complicated for STT-MRAM. However, because both read and write operations are performed by passing current through the MTJ 305, there is a potential for read operations to disturb the data stored in the MTJ 305. For example, if the read current is similar to or greater in magnitude than the write current threshold, then there is a substantial chance the read operation may disturb the logic state of MTJ 305 and thus degrade the integrity of the memory.

### SUMMARY

Exemplary embodiments of the invention are directed to systems, circuits and methods for read operations in STT-MRAM.

Accordingly, an embodiment of the invention can include a Spin Transfer Torque Magnetoresistive Random Access Memory (STT-MRAM) array comprising a plurality of bit cells, each coupled to one of a plurality of bit lines, word lines and source lines, and a plurality of precharge transistors, each corresponding to one of the plurality of bit lines, wherein the precharge transistors are configured to discharge the bit lines to ground, prior to a read operation.

Another embodiment of the invention can include a Spin Transfer Torque Magnetoresistive Random Access Memory (STT-MRAM) array comprising a plurality of bit cells, each coupled to one of a plurality of bit lines, word lines and source lines, a read mux configured to select one of the plurality of bit lines, and a precharge transistor coupled to an output of the read mux, wherein the precharge transistor is configured to discharge the selected bit line to ground, prior to a read operation.

Another embodiment of the invention can include a method for reading memory in a Spin Transfer Torque Magnetoresistive Random Access Memory (STT-MRAM) comprising discharging at least a selected bit line to a ground potential prior to a read operation, selecting a bit cell on the selected bit line, and reading a value of the bit cell during the read operation.

### BRIEF DESCRIPTION OF THE DRAWINGS

The accompanying drawings are presented to aid in the description of embodiments of the invention and are provided solely for illustration of the embodiments and not limitation thereof.

FIGS. 1A and 1B are illustrations of a magnetic tunnel junction (MTJ) storage element.

FIGS. 2A and 2B are illustrations of a Magnetoresistive Random Access Memory (MRAM) cell during read and write operations, respectively.

FIGS. 3A and 3B are illustrations of Spin Transfer Torque Magnetoresistive Random Access Memory (STT-MRAM) cells.

FIG. 4A is an illustration of a bit cell array of a STT-MRAM with a ground level precharge.

FIG. 4B is another illustration of a bit cell array of a STT-MRAM with a ground level precharge.

FIG. 5A is a graph illustrating the signal levels for a read operation of a STT-MRAM.

FIG. 5B is a graph illustrating another embodiment of the signal levels for a read operation of a STT-MRAM.

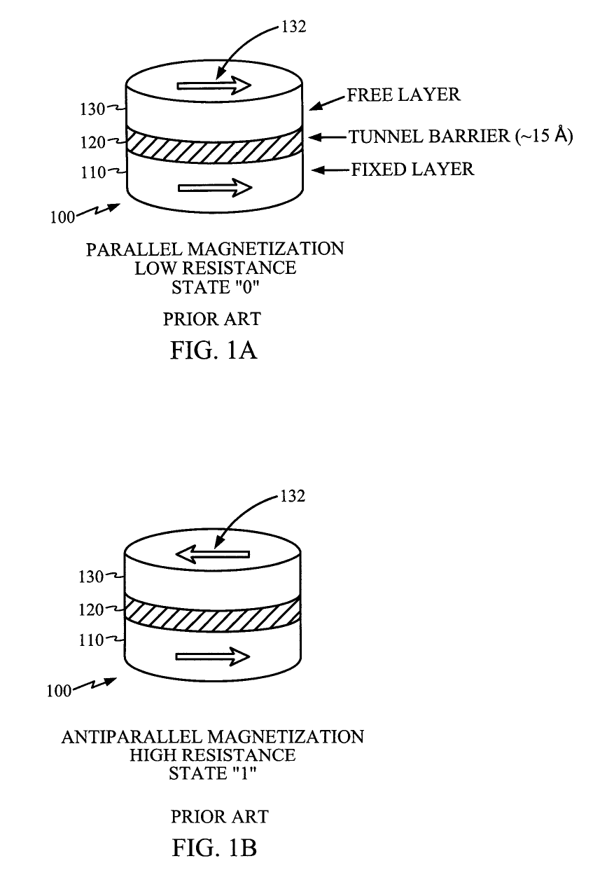

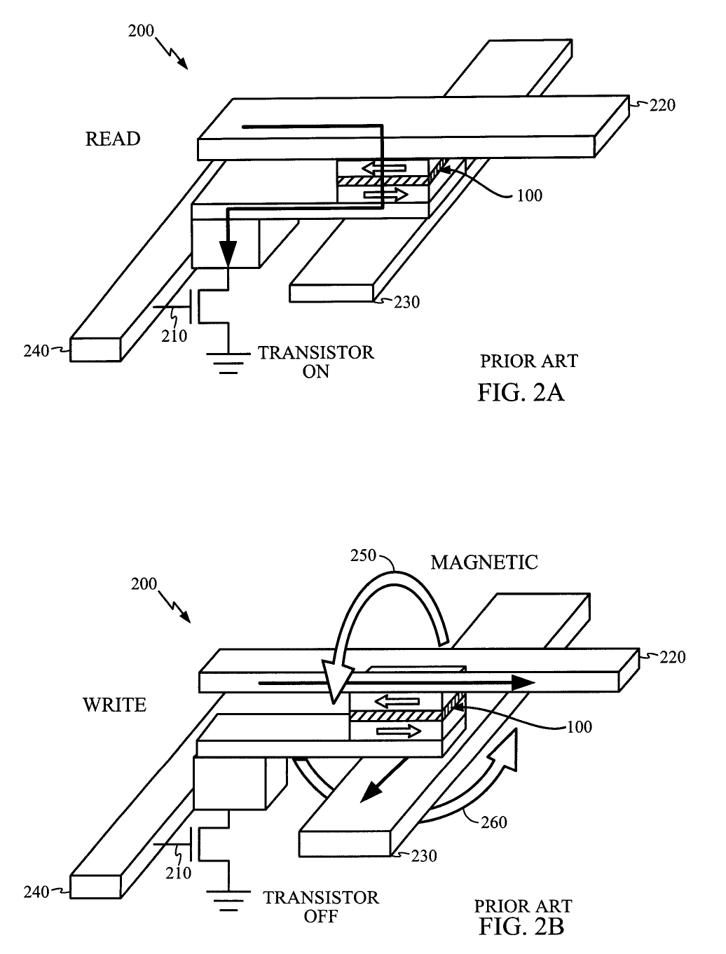

### DETAILED DESCRIPTION

Aspects of embodiments of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of embodiments of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

As discussed in the background, STT-MRAM uses a low write current for each cell, which is an advantage of this memory type over MRAM. However, cell read current can approach or be higher than the write current threshold and thus cause an invalid write operation to happen. To mitigate this problem, the bit line (BL) voltage level during read operation can be held to a lower value than the write threshold voltage.

Conventionally, the bit line (BL) voltage is precharged to a midpoint voltage (e.g., 0.4V). However, embodiments of the invention hold the BLs at a low or ground level during the precharge time. When a read command is asserted, the selected BL's multiplexer (mux) will be enabled. Through this mux, a current source (e.g., a PMOS transistor) provides a charge to BL. Unselected BLs stay at the low or ground level and there is no read disturb. The selected BL goes up to a certain voltage level, which is configured to be lower than the write threshold level. Also, embodiments can reduce read operating current and overall power consumption.

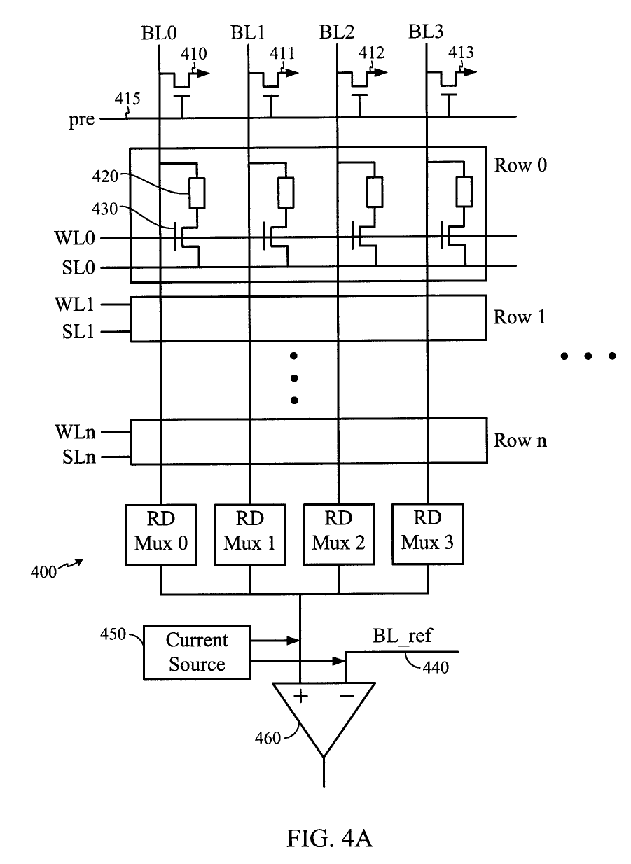

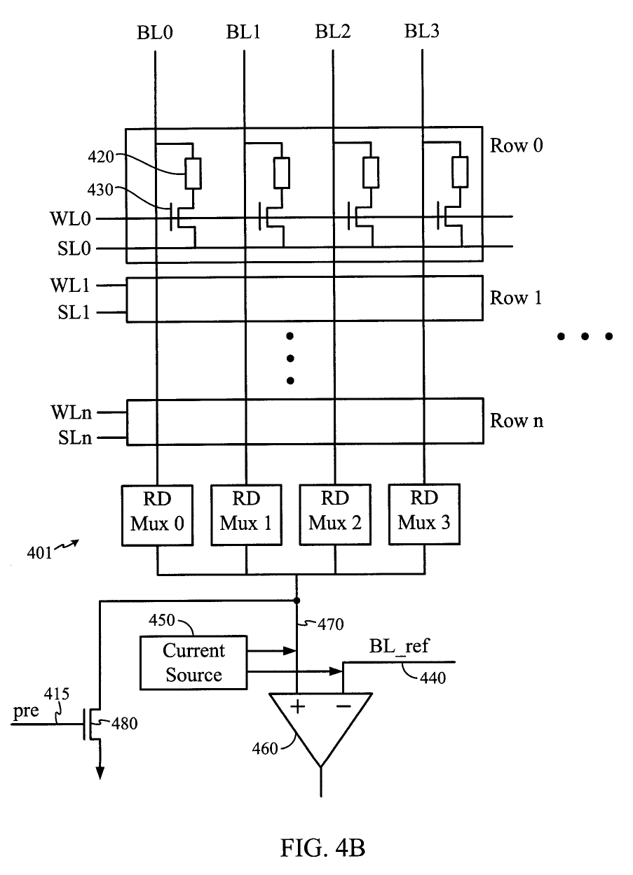

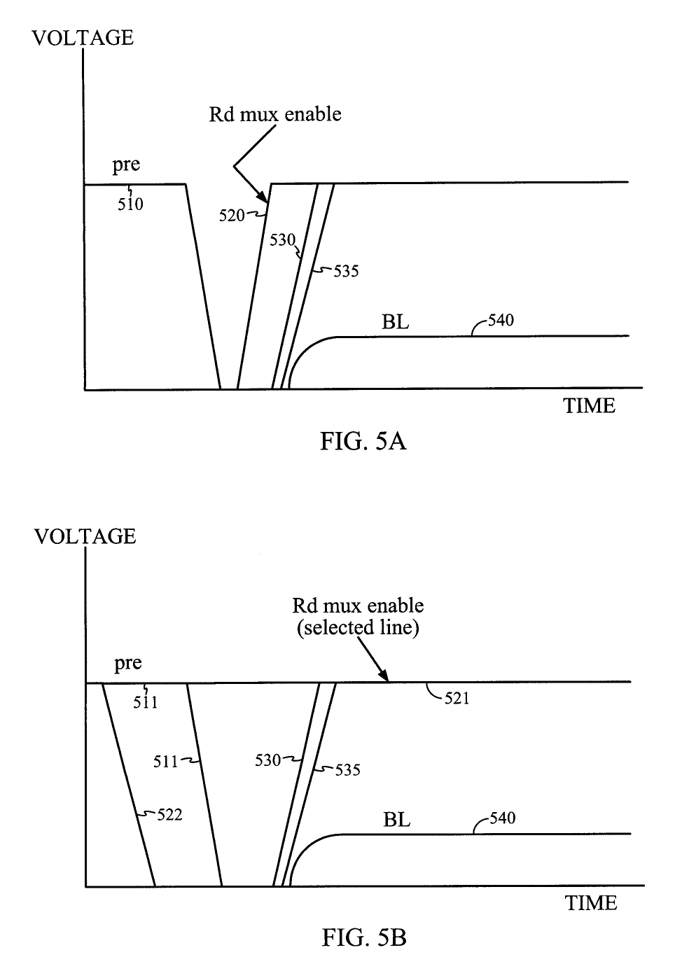

Referring to FIG. 4A, a section of a STT-MRAM array 400 is illustrated. For example, four bit lines BL0-BL3 are illustrated each having a precharge transistor 410-413 coupled to a precharge line 415. The precharge line 415 is activated prior to the read operation to establish a known reference value on the bit lines (BL0-BL3). When the precharge signal (pre) is active (high), embodiments of the invention discharge the bit lines to a low or ground potential via transistors 410-413. Additional details regarding the signaling will be discussed in relation to FIG. 5A below.

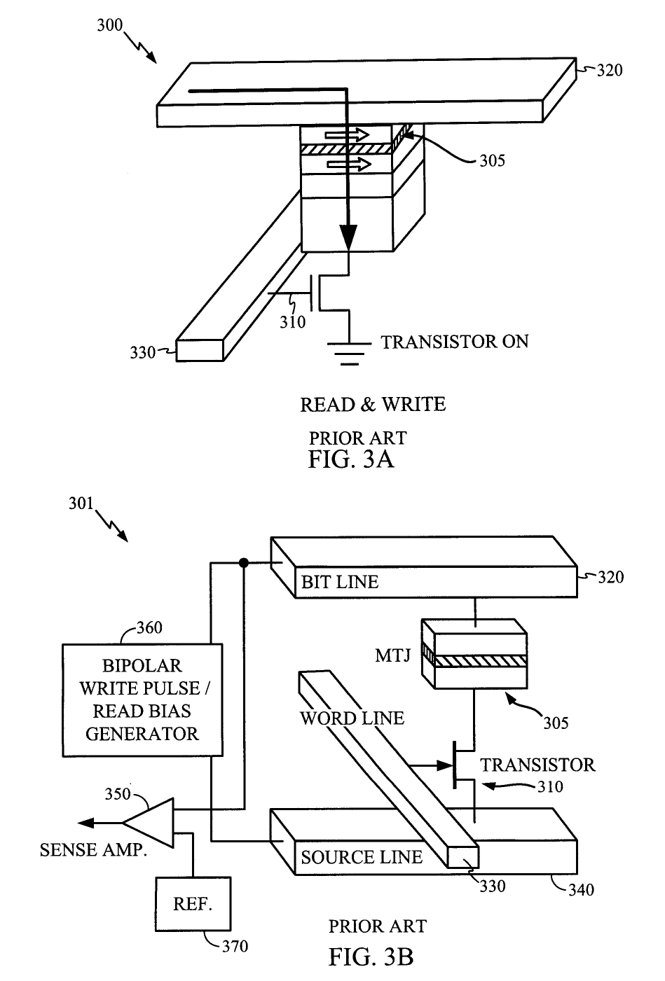

Each bit line (BL0-BL3) is coupled to a plurality of bit cells, conventionally arranged in rows (e.g., Row 0-Row n). Each row has an associated word line (WL0-WLn) and source line (SL0-SLn). Each bit includes an MTJ (e.g., 420) and a word line transistor (e.g., 430), as discussed in the background (see, e.g., FIGS. 3A and 3B). Each bit line BL0-BL3, has an associated read multiplexer (RD Mux0-RD Mux3) for selecting the bit line BL0-BL3 to be read. The row is determined by which word line is active. The bit cell is then selected based on the intersection of the bit line and the word line.

A current source 450 is provided for reading the value of the selected bit cell and the read value is compared to a reference value 440 (BL_Ref) that is coupled to sense amplifier 460. Sense amplifier 460 outputs a signal for the value of the bit cell based on a differential of the read value and the reference value. As discussed above, during the read operation, the unselected bit lines (e.g., BL1-BL3) will remain near the ground level after being discharged by the precharge transistors 410-413.

It will be appreciated that the foregoing circuit diagram is provided solely for purposes of illustration and the embodiments of the invention are not limited to this illustrated example. For example, the source line may be shared between multiple word lines, such as SL0 could be shared between WL0 and WL1. Likewise, the source line could be arranged to be parallel to the bit line, instead of substantially perpendicular to the bit line as illustrated. Further, other devices can be used that achieve the same functionality. For example, any switching device that selectively can couple the various bit lines could be used in place of read multiplexers.

FIG. 4B illustrates an alternative embodiment of a STT-MRAM array 401 having a ground level precharge on the bit lines. In the illustration, many of the elements are similar to those described in relation to FIG. 4A. Accordingly, common reference numbers will be used and a detailed discussion will be omitted.

Referring to FIG. 4B, a section of a STT-MRAM array 401 is illustrated. For example, four bit lines BL0-BL3 are illustrated. The precharge line 415 is activated prior to the read operation to establish a known reference value on the bit lines (BL0-BL3). In the array 401, instead of having a precharge transistor coupled to each bit line as illustrated in FIG. 4A, a shared precharge transistor 480 can be used. Upon receiving a precharge control signal (pre) on line 415, the precharge transistor 480 can be activated which will discharge the common bit line 470 to a ground potential. When a bit line (e.g., BL0) is selected via the read mux (e.g., RD Mux0), the bit line will be coupled to the common bit line input 470 to sense amp 460. In one embodiment, all bit lines BL0-3 can be selected by enabling the associated read multiplexers (or switches) RD Mux 0-3. The current source 450 can be disabled prior to the read operation (e.g., an enable signal corresponding with the word line enable) to prevent a current flow prior to the read operation, while the bit lines are discharged. It will be appreciated that the current source 450 in FIG. 4A may also be similarly disabled and then enabled during the read operation. Additional details regarding the signaling will be discussed in relation to FIG. 5B below.

FIG. 5A illustrates signaling for the circuit of FIG. 4A in accordance with embodiments of the invention. Precharge signal 510 (pre) is maintained at a high level prior to the read operation, which will activate the precharge transistor (see, e.g., 410 of FIG. 4A) and discharge the bit line to a ground potential. During the read operation the precharge signal 510 transitions to a low state and the precharge transistor will be gated off. Additionally, the read mux enable signal 520 (Rd mux enable) will be activated as will the word line enable signal 530 (WL). As discussed above, by enabling a particular read mux (e.g., RD Mux 0) a bit line can be selected (e.g., BL0). Likewise activating a particular word line will activate the associated word line transistors (e.g., 430) in a particular row. The intersection of the word line and bit line will select the particular bit cell to be read. The bit line voltage 540 will increase in proportion to the resistance of the MTJ (e.g., 420) and the current supplied by the current source (e.g., 450) when enabled by current source enable 535. As discussed above, the MTJ will have a different resistance value for each state (e.g., “0” and “1”). Accordingly, the bit line voltage 540 will change based upon the state of the MTJ and this change can be detected at the sense amplifier in relation to the reference value (e.g., BL_ref) to determine the value of the bit cell.

FIG. 5B illustrates signaling for the circuit of FIG. 4B in accordance with embodiments of the invention. Precharge signal 511 (pre) is maintained at a high level prior to the read operation, which will activate the precharge transistor (see, e.g., 480 of FIG. 4B). Additionally, the read mux enable signal 521 (Rd mux enable for the selected bit line) will be activated to allow for a selected bit line to couple to the precharge transistor and be discharged to a ground or low potential prior to the read operation. As illustrated, the selected bit line read mux enable 521 can be maintained on and the Rd mux enable signals 522 for the unselected bit lines can transition to a low state to decouple the unselected bit lines prior to the read operation. Alternatively, only the read mux enable 521 for the selected bit line can be activated prior to deactivating (e.g., 511) the precharge transistor. During the read operation the precharge signal 511 transitions to a low state and the precharge transistor will be deactivated (e.g., gated off). The word line enable signal 530 (WL) can be activated after the precharge transistor is gated off. Additionally, the current source (e.g., 450) can also be enabled (e.g., 535) after the precharge transistor is gated off. As discussed above, by enabling a particular read mux (e.g., RD Mux 0) a bit line can be selected (e.g., BL0). Likewise activating a particular word line will activate the associated word line transistors (e.g., 430) in a particular row. The intersection of the word line and bit line will select the particular bit cell to be read. The bit line voltage 540 will increase in proportion to the resistance of the MTJ (e.g., 420) and the current supplied by the current source (e.g., 450), which is enabled during the read operation by current source enable 535. As discussed above, the MTJ will have a different resistance value for each state (e.g., “0” and “1”). Accordingly, the bit line voltage 540 will change based upon the state of the MTJ and this change can be detected at the sense amplifier in relation to the reference value (e.g., BL_ref) to determine the value of the bit cell.

Although the foregoing disclosure shows illustrative embodiments of the invention, it will be appreciated that embodiments of the invention are not limited to these illustration. For example, the specific sequence of signals illustrated in FIGS. 5A and 5B may be modified as long as the functionality is maintained (e.g., read mux, word line and current source are enabled prior to a read of the bit cell). Further, embodiments of the invention can include methods for performing the functions, steps, sequence of actions and/or algorithms discussed herein. For example, an embodiment of the invention can include a method for reading memory in a Spin Transfer Torque Magnetoresistive Random Access Memory (STT-MRAM) comprising discharging at least a selected bit line to a ground potential prior to a read operation (see, e.g., 510 of FIG. 5A or 511 of FIG. 5B). A bit cell can be selected on a selected bit line (see, e.g., 520 and 530 of FIG. 5A or 521, 522 and 530 of FIG. 5B). Then, a value of the bit cell during the read operation (see, e.g., 540 of FIG. 5A or 5B).

While the foregoing disclosure shows illustrative embodiments of the invention, it should be noted that various changes and modifications could be made herein without departing from the scope of embodiments of the invention as defined by the appended claims. For example, specific logic signals corresponding to the transistors/circuits to be activated, may be changed as appropriate to achieve the disclosed functionality as the transistors/circuits may be modified to complementary devices (e.g., interchanging PMOS and NMOS devices). Likewise, the functions, steps and/or actions of the methods in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A Spin Transfer Torque Magnetoresistive Random Access Memory (STT-MRAM) array comprising:
a plurality of bit cells, each coupled to one of a plurality of bit lines, word lines and source lines; and
a plurality of precharge transistors, each corresponding to one of the plurality of bit lines, wherein the precharge transistors are configured to discharge the bit lines to ground, prior to a read operation.

2. The STT-MRAM array of claim 1, wherein the precharge transistors are NMOS transistors.

3. The STT-MRAM array of claim 1, wherein each bit cell comprises:
a storage element; and
a word line transistor coupled to the storage element.

4. The STT-MRAM array of claim 3, wherein the storage element is a magnetic tunnel junction (MTJ) and wherein the word line transistor is coupled in series with the MTJ.

5. The STT-MRAM array of claim 1, further comprising:
a sense amplifier having a first input coupled to a current source and a second input coupled to a bit line reference; and
a plurality of read multiplexers, wherein each read multiplexer corresponds to one of the bit lines and is configured to selectively couple the corresponding one of the bit lines to the first input of the sense amplifier.

6. A Spin Transfer Torque Magnetoresistive Random Access Memory (STT-MRAM) array comprising:
a plurality of bit cells, each coupled to one of a plurality of bit lines, word lines and source lines;
a read mux configured to select one of the plurality of bit lines; and
a precharge transistor coupled to an output of the read mux, wherein the precharge transistor is configured to discharge the selected bit line to ground, prior to a read operation.

7. The STT-MRAM array of claim 6, wherein the precharge transistor is a NMOS transistor.

8. The STT-MRAM array of claim 6, wherein each bit cell comprises:
a storage element; and
a word line transistor coupled to the storage element.

9. The STT-MRAM array of claim 8, wherein the storage element is a magnetic tunnel junction (MTJ) and wherein the word line transistor is coupled in series with the MTJ.

10. The STT-MRAM array of claim 6, further comprising:
a sense amplifier having a first input coupled to a current source and the output of the read mux and a second input coupled to a bit line reference.

11. A method for a reading memory in a Spin Transfer Torque Magnetoresistive Random Access Memory (STT-MRAM) comprising:
discharging at least a selected bit line to a ground potential prior to a read operation;
selecting a bit cell on the selected bit line; and
reading a value of the bit cell during the read operation.

12. The method of claim 11, further comprising:
selecting the selected bit line using a read multiplexer;
activating a word line coupled to the bit cell; and
sourcing a current on the selected bit line to read the bit cell.

13. The method of claim 12, wherein the bit cell comprises:
a magnetic tunnel junction (MTJ); and
a word line transistor coupled in series with the MTJ.

14. The method of claim 11, further comprising:
discharging at least one of a plurality of bit lines prior to the read operation.

15. The method of claim 14, wherein the plurality of bit lines includes the selected bit line and each bit line has an associated precharge transistor coupled to the bit line to discharge the bit line.

16. The method of claim 15, further comprising:
deactivating the precharge transistor prior to enabling a read mux coupled to the plurality of bit lines.

17. The method of claim 14, wherein the plurality of bit lines includes the selected bit line and a precharge transistor is coupled to the selected bit line to discharge the selected bit line.

18. The method of claim 17, further comprising:
deactivating the precharge transistor after enabling a read multiplexer coupled to the plurality of bit lines, wherein the precharge transistor is coupled to the selected bit line at an output of the read multiplexer.
